(19) United States
(12) Patent Application Publication
(10) Pub. No.: US 2025/0391799 A1
(43) Pub. Date: Dec. 25, 2025

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/226,174

(22) Filed: Jun. 3, 2025

(30) Foreign Application Priority Data
Jun. 21, 2024 (TW) 113123162

(51) Int. Cl. H01L 23/00

(52) U.S. Cl. CPC H01L 24/24; H01L 2224/24011; H01L 2224/24226

(57) ABSTRACT

A fan-out wafer level packaging (FOWLP) unit which includes a substrate, at least one die, a first dielectric layer, a second dielectric layer, a plurality of first conductive circuits, a third dielectric layer, a fourth dielectric layer, a plurality of second conductive circuits, and an outer protective layer is provided. The first conductive circuits are produced on a second surface of the die by filling a metal paste into slots and grinding the metal paste. The second conductive circuits are produced on the second dielectric layer and the plurality of the first conductive circuits by filling a metal paste into slots and grinding the metal paste. The die is electrically connected to the outside by bonding pads around a chip area on the second surface of the die. Thereby problems of conventional FOWLP including higher manufacturing cost and less environmental benefit can be solved.

### CROSS-REFERENCE TO RELATED APPLICATIONS

This non-provisional application claims priority under 35 U.S.C. § 119 (a) on Patent Application No(s). 113123162 filed in Taiwan, R.O.C. on Jun. 21, 2024, the entire contents of which are hereby incorporated by reference.

### BACKGROUND OF THE INVENTION

The present invention relates to a chip packaging unit, especially to a fan-out wafer level packaging (FOWLP) unit.

Packaging technology with features of compact design, high efficiency, and high reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, in order to meet requirements for multiple applications, the layout design in the FOWLP uses at least two redistribution layers (RDL) and the multi-chip FOWLP is formed by integration of RDL. Thus space requirement for respective conductive circuit design in RDL of the FOWLP is increased and manufacturing techniques of the respective conductive circuits in RDL are getting more important.

### SUMMARY OF THE INVENTION

Therefore, it is a primary object of the present invention to provide a fan-out wafer level packaging (FOWLP) unit which includes a substrate, at least one die, a first dielectric layer, a second dielectric layer, a plurality of first conductive circuits, a third dielectric layer, a fourth dielectric layer, a plurality of second conductive circuits, and an outer protective layer. The first conductive circuits are produced and formed on a second surface of the die by filling a metal paste into slots and grinding the metal paste. The second conductive circuits are produced and formed on the second dielectric layer and the plurality of the first conductive circuits by filling a metal paste into slots and grinding the metal paste. The die is electrically connected to the outside by bonding pads around a chip area on the second surface of the die. Thereby the problems of the FOWLP technology available now generated during manufacturing of the respective conductive circuits including higher manufacturing cost and less environmental benefit can be solved.

In order to achieve the above object, a fan-out wafer level packaging (FOWLP) unit according to the present invention includes a substrate, at least one die, a first dielectric layer, a second dielectric layer, a plurality of first conductive circuits, a third dielectric layer, a fourth dielectric layer, a plurality of second conductive circuits, and an outer protective layer. The die is cut from a wafer and arranged at the substrate. The die is provided with a first surface and a second surface opposite to the first surface. The first surface of the die is fixed on the substrate while the second surface of the die is provided with a plurality of die pads. A range perpendicular to the second surface of the die is defined as a chip area. The first dielectric layer is mounted to the substrate and the second surface of the dies and provided with a plurality of first slots extending in a horizontal direction. The respective die pads of the die are exposed through the respective first slots. The second dielectric layer is disposed over the first dielectric layer and provided with a plurality of second slots extending in a horizontal direction. The respective second slots are communicating with the respective first slots. The first conductive circuits are formed by a metal paste filled in both the first slots and the second slots and electrically connected with the die pads of the die. The third dielectric layer is disposed over the second dielectric layer and provided with a plurality of third slots extending in a horizontal direction. The respective third slots are communicating with the respective second slots. The fourth dielectric layer is arranged over the third dielectric layer and provided with a plurality of fourth slots extending in a horizontal direction. The respective fourth slots are communicating with the respective third slots. The second conductive circuits are formed by a metal paste filled in both the third slots and the fourth slots and electrically connected with the first conductive circuits correspondingly. The outer protective layer is arranged over the fourth dielectric layer and provided with a plurality of openings. At least two of the openings are located around the chip area on the second surface of the die. Each of the second conductive circuits is exposed through the corresponding opening to form a bonding pad in the corresponding opening. The die is electrically connected to the outside through the respective die pads, the respective first conductive circuits, the respective second conductive circuits, and the respective bonding pads located around the chip area on the second surface of the die in turn. Thereby the FOWLP unit is formed.

A method of manufacturing the FOWLP unit includes the following steps.

Step S1: providing a substrate 10.
Step S2: arranging a plurality of dies cut from the same wafer or different wafers on the substrate with an interval between the two adjacent dies and each of the dies having a first surface and a second surface opposite to each other. The first surface of the die is arranged at the substrate while the second surface of the die is provided with a plurality of die pads. A range perpendicular to the second surface of the die is defined as a chip area.
Step S3: producing a plurality of first conductive circuits on the second surface of the respective dies by filling metal paste into slots and grinding the metal paste. First paving a first dielectric layer over the substrate and the second surface of the respective dies, forming a plurality of first slots extending horizontally on the first dielectric layer, and exposing the respective die pads of the respective dies through the respective first slot. Then arranging a second dielectric layer over the first dielectric layer, forming a plurality of second slots extending horizontally on the second dielectric layer, and communicating the second slots with the first slots correspondingly. Next filling a metal paste into the respective first slots and the respective second slots and allowing a level of the metal paste higher than a surface of the second dielectric layer. Lastly, grinding the metal paste with the level higher than the surface of the second dielectric layer to make a surface of the metal paste flush with the surface of the second dielectric layer and form a plurality of the first conductive circuits.
Step S4: producing a plurality of second conductive circuits on the second dielectric layer and the plurality of the first conductive circuits by filling a metal paste into slots and grinding the metal paste. First paving a third dielectric layer over the second dielectric layer, forming a plurality of third slots extending horizontally on the third dielectric layer, and communicating the third slots with the second slots correspondingly. Then arranging a fourth dielectric layer over the third dielectric layer, forming a plurality of fourth slots extending horizontally on the fourth dielectric layer, and communicating the fourth slots with the third slots correspondingly. Next filling a metal paste into the third slots and the fourth slots and allowing a level of the metal paste higher than a surface of the fourth dielectric layer. Lastly, grinding the metal paste with the level higher than the surface of the fourth dielectric layer to make a surface of the metal paste flush with the surface of the fourth dielectric layer and form a plurality of the second conductive circuits. The respective second conductive circuits are electrically connected with the respective first conductive circuits.
Step S5: covering the fourth dielectric layer with an outer protective layer.
Step S6: forming a plurality of openings on the outer protective layer and at least one of the openings is formed around the chip area on the second surface of the respective dies so that the respective second conductive circuits are exposed through the respective openings to form a bonding pad in each of the openings.
Step S7: performing cutting to form a plurality of the FOWLP units each of which includes at least one of the dies.

Preferably, the FOWLP unit further includes at least two dies. In the step S7 of the method of manufacturing the FOWLP unit, performing cutting to form a plurality of the FOWLP units each of which includes at least two of the dies.

Preferably, the substrate can be silicon (Si) substrate, glass substrate, or ceramic substrate.

Preferably, the metal paste of the first conductive circuits and the second conductive circuits includes silver paste, nano-scale silver paste, copper paste, and nano-scale copper paste.

Preferably, the first surface of the die is arranged at the substrate by a die attach film (DAF).

Preferably, a solder ball is disposed on the opening and electrically connected to the bonding pad inside the opening. The FOWLP unit is electrically connected and mounted to a printed circuit board (PCB) by the solder ball.

### BRIEF DESCRIPTION OF THE DRAWINGS

FIG. 1 is a side sectional view of an embodiment of a FOWLP unit disposed on a printed circuit board according to the present invention;

FIG. 2 is a side sectional view showing dies arranged at a substrate of an embodiment according to the present invention;

FIG. 3 is a side sectional view showing a first dielectric layer disposed on a substrate and a second surface of respective dies of an embodiment according to the present invention;

FIG. 4 is a side sectional view showing a second dielectric layer disposed on a first dielectric layer of an embodiment according to the present invention;

FIG. 5 is a side sectional view showing first slots and second slots both filled with metal paste of an embodiment according to the present invention;

FIG. 6 is a side sectional view showing grinding of the metal paste with a level higher than a surface of the second dielectric layer in the embodiment in FIG. 5 according to the present invention;

FIG. 7 is a side sectional view showing a third dielectric layer disposed on a second dielectric layer of an embodiment according to the present invention;

FIG. 8 is a side sectional view showing a fourth dielectric layer disposed on a third dielectric layer of an embodiment according to the present invention;

FIG. 9 is a side sectional view showing third slots and fourth slots both filled with metal paste of an embodiment according to the present invention;

FIG. 10 is a side sectional view showing grinding of the metal paste with a level higher than a surface of a fourth dielectric layer in the embodiment in FIG. 9 according to the present invention;

FIG. 11 is a side sectional view showing formation of a plurality of openings on an outer protective layer of an embodiment according to the present invention;

FIG. 12 is a side sectional view showing a fan-out wafer-level packaging (FOWLP) unit provided with solder balls of an embodiment according to the present invention;

FIG. 13 is a side sectional view showing a fan-out wafer-level packaging (FOWLP) unit provided with solder balls of another embodiment according to the present invention;

FIG. 14 is a side sectional view showing a fan-out wafer-level packaging (FOWLP) unit disposed on a printed circuit board (PCB) of an embodiment according to the present invention.

### DETAILED DESCRIPTION OF THE PREFFERED EMBODIMENT

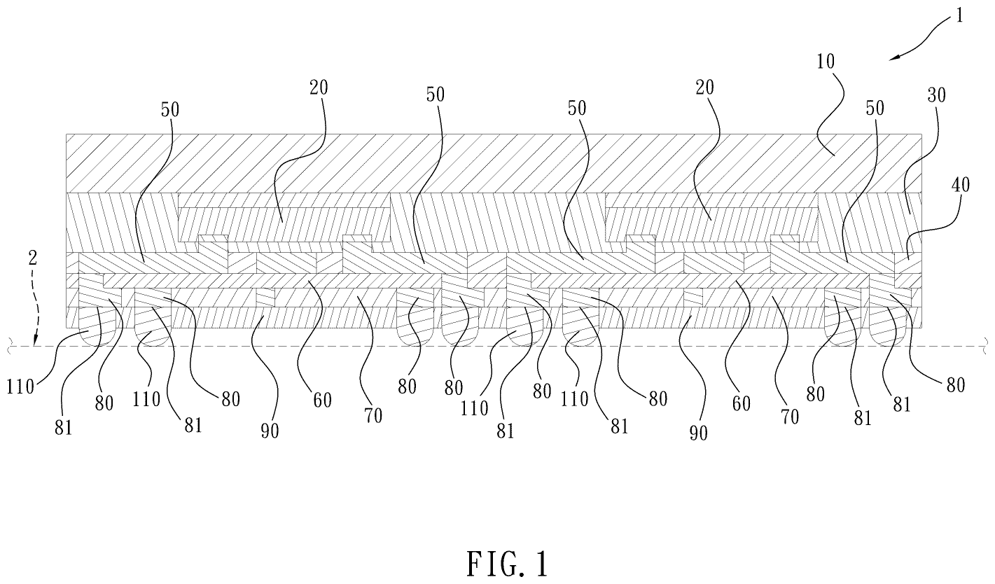

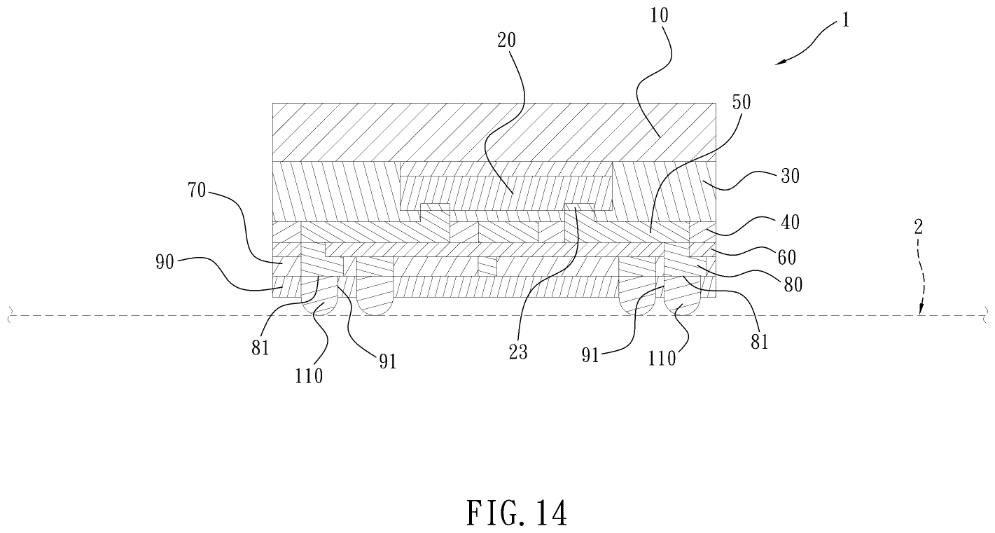

Refer to FIG. 1 and FIG. 14, a fan-out wafer-level packaging (FOWLP) unit 1 according to the present invention includes a substrate 10, at least one die 20, a first dielectric layer 30, a second dielectric layer 40, a plurality of first conductive circuits 50, a third dielectric layer 60, a fourth dielectric layer 70, a plurality of second conductive circuits 80, and an outer protective layer 90.

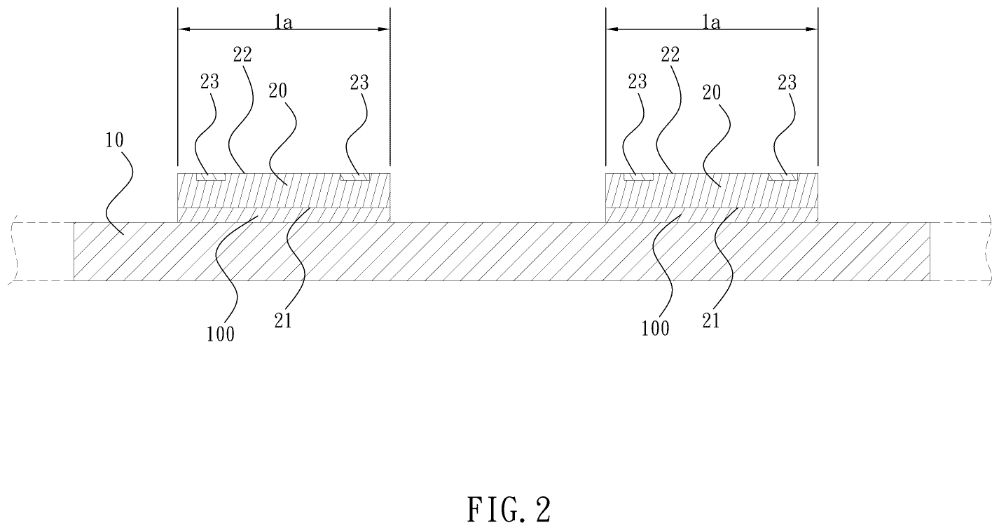

The die 20 is cut from a wafer and arranged at the substrate 10. The die 20 is provided with a first surface 21 and a second surface 22 opposite to the first surface 21. The first surface 21 of the die 20 is fixed on the substrate 10 while the second surface 22 of the die 20 is provided with a plurality of die pads 23. A range perpendicular to the second surface 22 of the die 20 is defined as a chip area 1a, as shown in FIG. 2. There are two die pads 23 on the die 20 in FIG. 2 but the number of the die pads 23 is not limited.

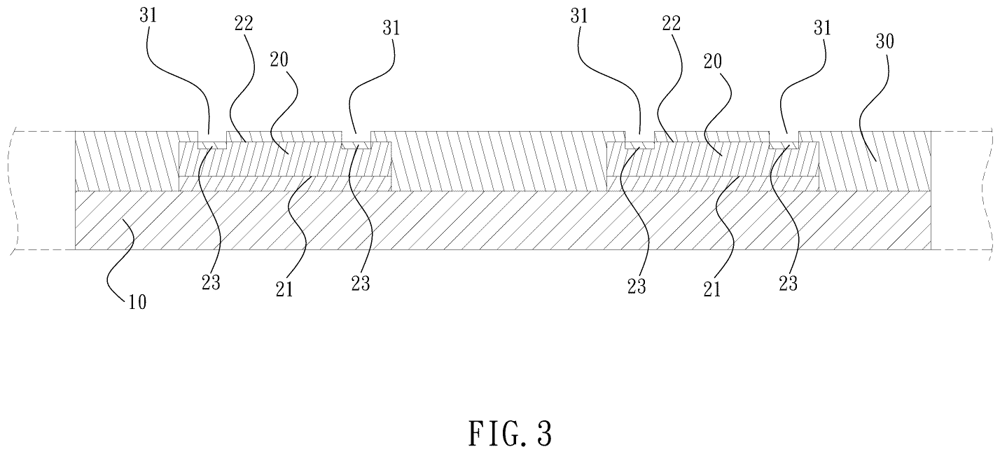

Refer to FIG. 3, the first dielectric layer 30 is mounted to the substrate 10 and the second surface 22 of the dies 20 and provided with a plurality of first slots 31 extending in a horizontal direction. The respective die pads 23 of the dies 20 are exposed through the respective first slots 31.

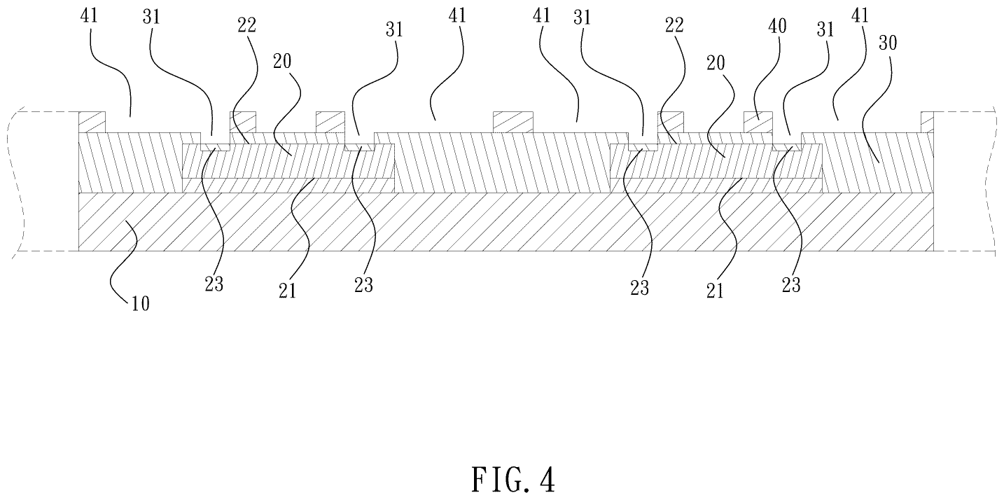

The second dielectric layer 40 is disposed over the first dielectric layer 30 and provided with a plurality of second slots 41 extending in a horizontal direction. The respective second slots 41 are communicating with the respective first slots 31, as shown in FIG. 4.

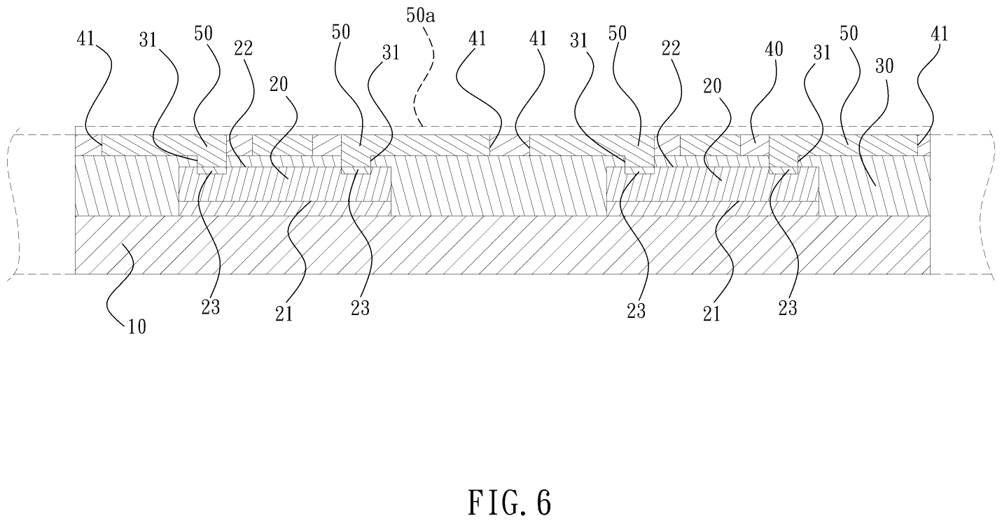

The respective first conductive circuits 50 are formed by a metal paste 50a filled in the respective first slots 31 and the respective second slots 41. The respective conductive circuits 50 are electrically connected with the respective die pads 23 of the respective dies, as shown in FIG. 6.

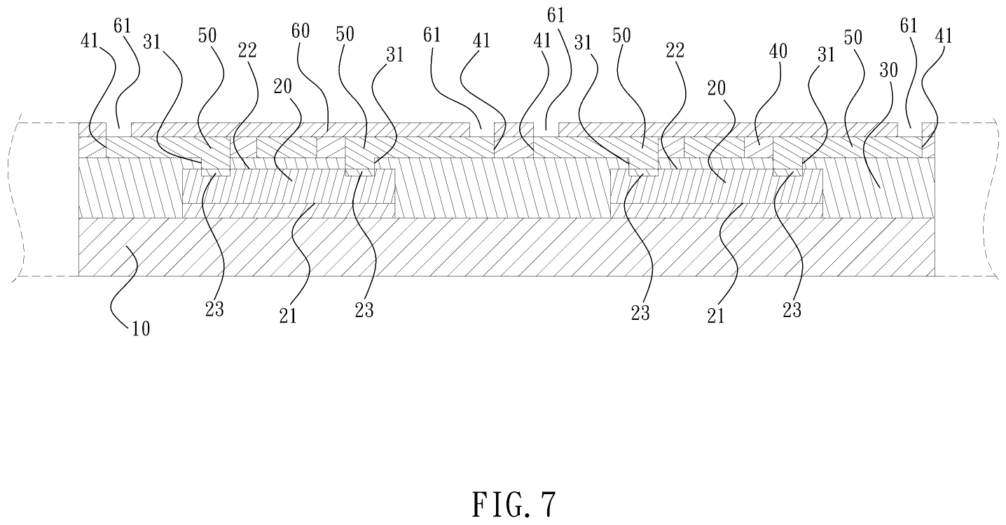

The third dielectric layer 60 is disposed over the second dielectric layer 40 and provided with a plurality of third slots 61 extending in a horizontal direction. The respective third slots 61 are communicating with the respective second slots 41, as shown in FIG. 7.

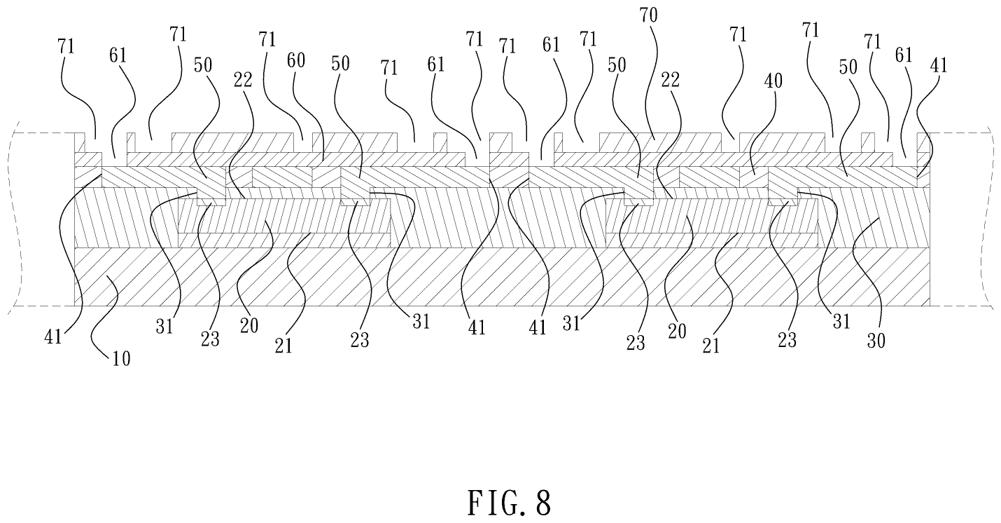

The fourth dielectric layer 70 is arranged over the third dielectric layer 60 and provided with a plurality of fourth slots 71 extending in a horizontal direction. The respective fourth slots 71 are communicating with the respective third slots 61, as shown in FIG. 8.

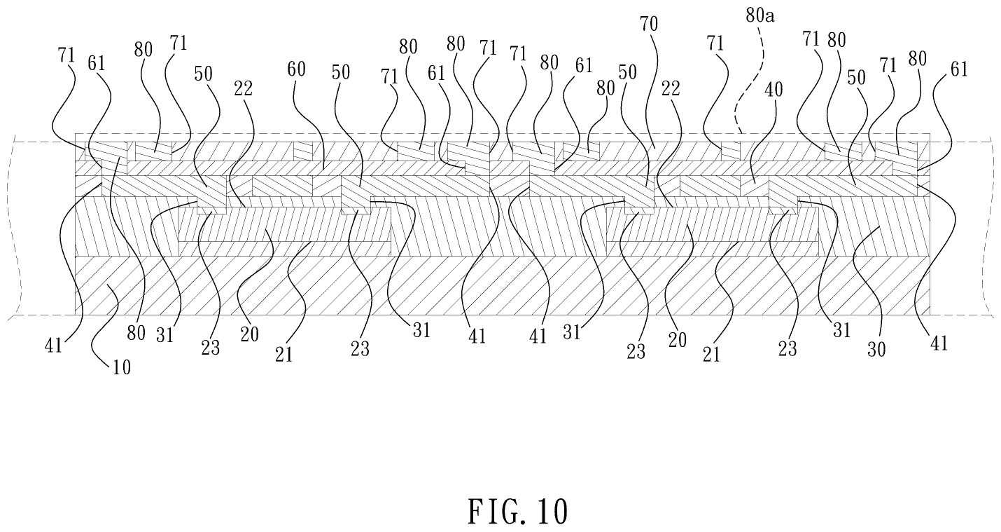

The respective second conductive circuits 80 are formed by a metal paste 80a filled in both the respective third slots 61 and the respective fourth slots 71 and electrically connected with the respective first conductive circuits 50, as shown in FIG. 10.

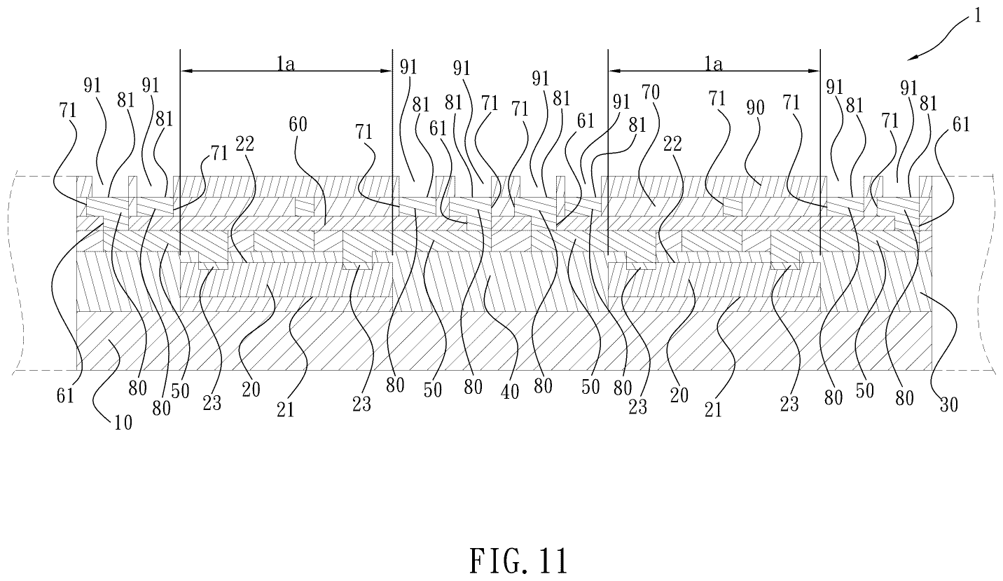

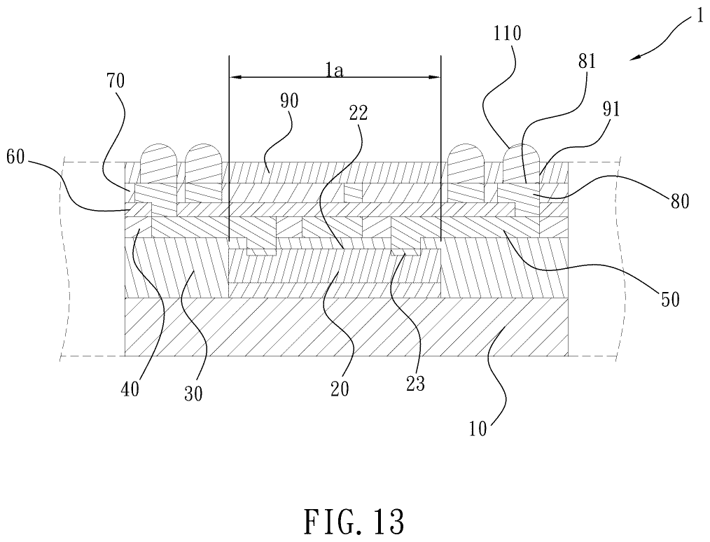

The outer protective layer 90 is mounted over the fourth dielectric layer 70 and provided with a plurality of openings 91. At least two of the openings 91 are located around the chip area 1a on the second surface 22 of the die 20, as shown in FIG. 11. Each of the second conductive circuits 80 is exposed through the corresponding opening 91 to form a bonding pad 81 in the corresponding opening 91, as shown in FIG. 11 and FIG. 13. There are eight openings 91 in the outer protective layer 90 in FIG. 11 but this is not intended to limit the present invention. The number of the openings 91 is not limited.

The dies 20 are electrically connected to the outside through the respective die pads 23, the respective first conductive circuits 50, the respective second conductive circuits 80, and the respective bonding pads 81 located around the chip area 1a on the second surface 22 of the die 20 in turn. Thereby the fan-out wafer-level packaging (FOWLP) unit 1 is formed, as shown in FIG. 11 and FIG. 13.

A method of manufacturing the FOWLP unit 1 includes the following steps.

Step S1: providing a substrate 10, as shown in FIG. 2.

Step S2: arranging a plurality of dies 20 cut from the same wafer or different wafers on the substrate 10 with an interval between the two adjacent dies 20, as shown in FIG. 2. Each of the dies 20 includes a first surface 21 and a second surface 22 opposite to the first surface 21. The first surface 21 of the die 20 is arranged at the substrate 10 while the second surface 22 of the die 20 is provided with a plurality of die pads 23. A range perpendicular to the second surface 22 of the die 20 is defined as a chip area 1a, as shown in FIG. 2.

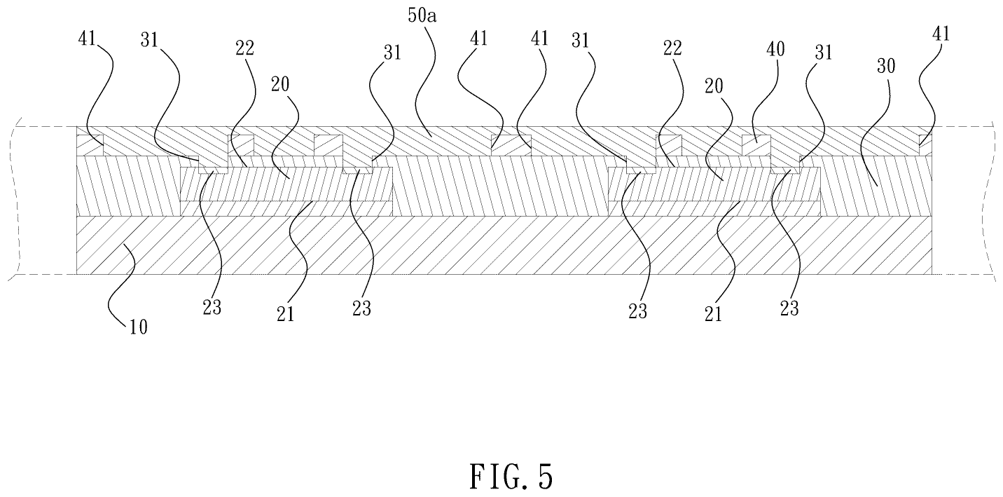

Step S3: producing a plurality of first conductive circuits 50 on the second surface 22 of the respective dies 20 by filling metal paste into slots and grinding the metal paste. First paving a first dielectric layer 30 over the substrate 10 and the second surface 22 of the respective dies 20, forming a plurality of first slots 31 extending horizontally on the first dielectric layer 30, and exposing the respective die pads 23 of the respective dies 20 through the respective first slots 31, as shown in FIG. 3. Then arranging a second dielectric layer 40 over the first dielectric layer 30, forming a plurality of second slots 41 extending horizontally on the second dielectric layer 40, and communicating the second slots 41 with the first slots 31 correspondingly, as shown in FIG. 4. Next filling a metal paste 50a into the respective first slots 31 and the respective second slots 41 and allowing a level of the metal paste 50a higher than a surface of the second dielectric layer 40, as shown in FIG. 5. Lastly, grinding the metal paste 50a with the level higher than the surface of the second dielectric layer 40 to make a surface of the metal paste 50a flush with the surface of the second dielectric layer 40 and form a plurality of first conductive circuits 50, as shown in FIG. 6.

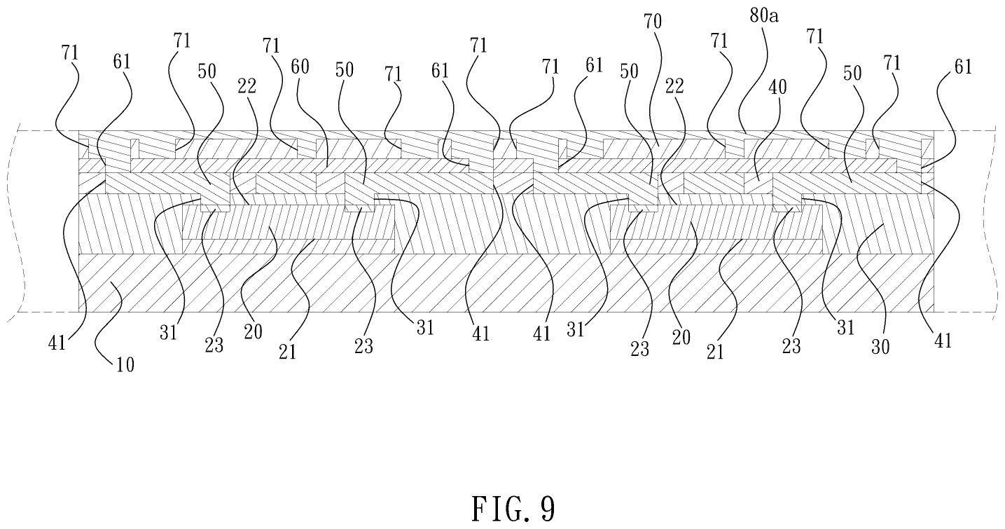

Step S4: producing a plurality of second conductive circuits 80 on the second dielectric layer 40 and the plurality of the first conductive circuits 50 by filling metal paste into slots and grinding the metal paste. First paving a third dielectric layer 60 over the second dielectric layer 40, forming a plurality of third slots 61 extending horizontally on the third dielectric layer 60, and communicating the third slots 61 with the second slots 41 correspondingly, as shown in FIG. 7. Then arranging a fourth dielectric layer 70 over the third dielectric layer 60, forming a plurality of fourth slots 71 extending horizontally on the fourth dielectric layer 70, and communicating the fourth slots 71 with the third slots 61 correspondingly, as shown in FIG. 8. Next filling a metal paste 80a into the respective third slots 61 and the respective fourth slots 71 and allowing a level of the metal paste 80a higher than a surface of the fourth dielectric layer 70, as shown in FIG. 9. Lastly, grinding the metal paste 80a with the level higher than the surface of the fourth dielectric layer 70 to make a surface of the metal paste 80a flush with the surface of the fourth dielectric layer 70 and form a plurality of the second conductive circuits 80, as shown in FIG. 10. The respective second conductive circuits 80 are electrically connected with the first conductive circuits 50, as shown in FIG. 10.

Step S5: covering the fourth dielectric layer 70 with an outer protective layer 90, as shown in FIG. 11.

Step S6: forming a plurality of openings 91 on the outer protective layer 90 and at least one of the openings 91 is formed around the chip area 1a on the second surface 22 of the respective dies 20 so that the respective second conductive circuits 80 are exposed through the respective openings 91 to form a bonding pad 81 in each of the openings 91, as shown in FIG. 11.

Step S7: performing cutting to form a plurality of the fan-out wafer-level packaging (FOWLP) units 1 each of which includes at least one of the dies 20, as shown in FIG. 13.

The steps S3-S4 are considered as key steps of manufacturing the redistribution layer (RDL) of the FOWLP unit 1. The steps S3-S4 are easy to be implemented precisely so that the manufacturing process is simplified and the respective first and the second conductive circuits 50, 80 in the RDL have electrical extension in the XY plane and interconnections. At the same time, the FOWLP unit 1 manufactured still has slim size and light weight to a certain degree. Even the FOWLP unit 1 includes at least two of the dies 20, it's still compact and light weight to a certain degree.

Refer to FIG. 2, the substrate 10 includes silicon (Si) substrate, glass substrate, and ceramic substrate. This is beneficial to diversified product development and applications.

Refer to FIG. 6, the metal paste 50a, 80a which forms the first conductive circuits 50 and the second conductive circuits 80 includes, but not limited to silver paste, nano-scale silver paste, copper paste, and nano-scale copper paste. The nano-scale silver paste has features of low cost, high conductivity, and low temperature sintering.

Refer to FIG. 2, the first surface 21 of the die 20 is arranged at the substrate 10 by a die attach film (DAF) 100.

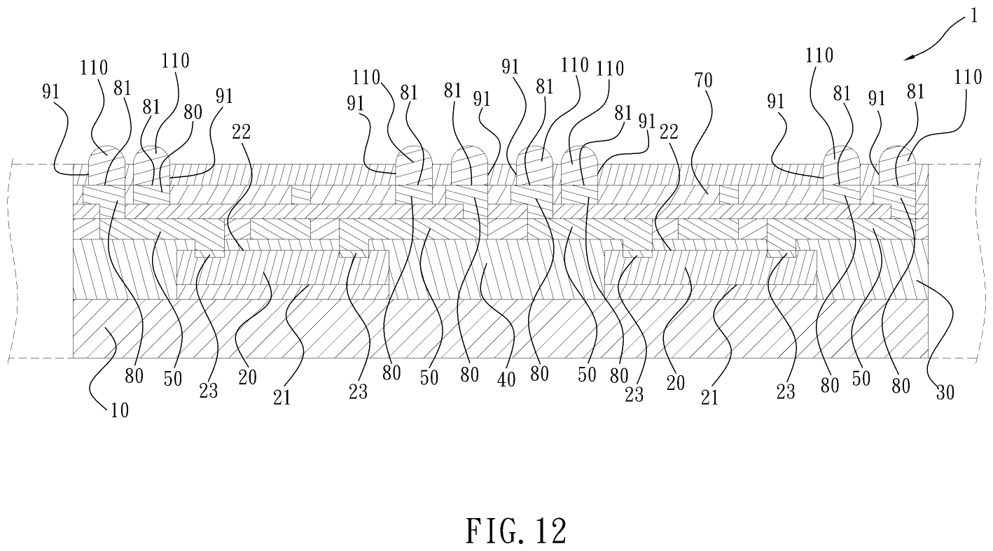

Refer to FIG. 12 and FIG. 13, a solder ball 110 is disposed on the opening 91 and electrically connected to the bonding pad 81 inside the opening 91. Refer to FIG. 1 and FIG. 14, the FOWLP unit 1 is electrically connected and mounted to a printed circuit board (PCB) 2 by the solder balls 110.

In a preferred embodiment, the FOWLP unit further includes at least two dies 20, as shown in FIG. 11. The two dies 20 are cut from the same wafer or different wafers and arranged at the substrate 10 in parallel and spaced apart from each other. Each of the dies 20 is provided with a first surface 21 and a second surface 22 opposite to the first surface 21. The first surface 21 of the die 20 fixed on the substrate 10 while the second surface 22 of the die 20 is provided with a plurality of die pads 23 and a range) perpendicular to the second surface 22 is defined as a chip area 1a, as shown in FIG. 11. When the dies 20 are cut from the same wafer, the respective dies 20 have the same specifications, effectiveness, or functions. When the dies 20 are cut from different wafers, the respective dies 20 have different specifications, effectiveness, or functions. This helps diversified applications of the product. Moreover, when the FOWLP unit 1 further includes at least two dies 20, the method of manufacturing the FOWLP unit 1 still includes the step S1 to step S6 mentioned above. Only the step S7 is changed into performing cutting to form a plurality of the FOWLP units 1 each of which includes at least two of the dies 20, as shown in FIG. 11.

Compared with the FOWLP unit available now, the present FOWLP unit 1 has the following advantages.

(1) The steps S3-S4 of the present method of manufacturing the present FOWLP unit 1 are simplified and easily-implemented steps and this is especially helpful in reduction of a thickness of the packaging unit. Thus the manufacturing process of the present invention is not only more simplified and with reduced cost, but also improving use efficiency and reliability of the FOWLP unit 1.
(2) The plurality of the first conductive circuits 50 and the second conductive circuits 80 of the present invention are formed by filling metal paste into the slots and then grinding the metal paste. Thus the problems of the FOWLP technology available now generated during manufacturing of the respective conductive circuits including higher manufacturing cost and less environmental benefit can be solved effectively by the present invention.
(3) The dies 20 are electrically connected to the outside through the respective die pads 23, the respective first conductive circuits 50, the respective second conductive circuits 80, and the respective bonding pads 81 located around the chip area 1a on the second surface 22 of the die 20 in turn. Under the condition that the respective conductive circuits in the RDL have electrical extension in the XY plane and interconnections, the FOWLP unit with multiple chips can still achieve slim size and light weight to a certain degree.

1. A fan-out wafer level packaging (FOWLP) unit comprising:
a substrate;
at least one die cut from a wafer, arranged at the substrate, and having a first surface and a second surface opposite to each other; the first surface of the die fixed on the substrate while the second surface of the die provided with a plurality of die pads; a range perpendicular to the second surface of the die being defined as a chip area;
a first dielectric layer mounted to the substrate and the second surface of the die and provided with a plurality of first slots extending horizontally; wherein each of the die pads of the die is exposed through the corresponding first slot;
a second dielectric layer disposed over the first dielectric layer and provided with a plurality of second slots extending horizontally and communicating with the first slots;
a plurality of first conductive circuits formed by a metal paste filled in both the first slots and the second slots and electrically connected with the die pads of the die;
a third dielectric layer disposed over the second dielectric layer and provided with a plurality of third slots extending horizontally and communicating with the second slots;
a fourth dielectric layer arranged over the third dielectric layer and provided with a plurality of fourth slots extending horizontally and communicating with the third slots;
a plurality of second conductive circuits formed by a metal paste filled in both the third slots and the fourth slots and electrically connected with the first conductive circuits correspondingly;
an outer protective layer arranged over the fourth dielectric layer and provided with a plurality of openings; at least two of the openings located around the chip area on the second surface of the die; wherein each of the second conductive circuits is exposed through the corresponding opening to form a bonding pad in the corresponding opening;
wherein the die is electrically connected to the outside through the die pads, the first conductive circuits, the second conductive circuits, and the bonding pads located around the chip area on the second surface of the die in turn; thereby the FOWLP unit is formed;
wherein a method of manufacturing the FOWLP unit comprising the steps of:
Step S1: providing a substrate;
Step S2: arranging a plurality of dies cut from the same wafer or different wafers on the substrate with an interval between the two adjacent dies; wherein each of the dies includes a first surface and a second surface opposite to the first surface; the first surface of the die is arranged at the substrate and the second surface of the die is provided with a plurality of die pads; a range perpendicular to the second surface of the die is defined as a chip area;
Step S3: producing a plurality of first conductive circuits on the second surface of the respective dies by filling metal paste into slots and grinding the metal paste; first paving a first dielectric layer over the substrate and the second surface of the die, forming a plurality of first slots extending horizontally on the first dielectric layer, and exposing the die pads of the die through the corresponding first slots; then arranging a second dielectric layer over the first dielectric layer, forming a plurality of second slots extending horizontally on the second dielectric layer, and communicating the second slots with the first slots correspondingly; later filling a metal paste into the first slots and the second slots and allowing a level of the metal paste higher than a surface of the second dielectric layer; lastly, grinding the metal paste with the level higher than the surface of the second dielectric layer to make a surface of the metal paste flush with the surface of the second dielectric layer and form a plurality of first conductive circuits;
Step S4: producing a plurality of second conductive circuits on the second dielectric layer and the plurality of the first conductive circuits by filling a metal paste into slots and grinding the metal paste; first paving a third dielectric layer over the second dielectric layer, forming a plurality of third slots extending horizontally on the third dielectric layer, and communicating the third slots with the second slots correspondingly; then arranging a fourth dielectric layer over the third dielectric layer, forming a plurality of fourth slots extending horizontally on the fourth dielectric layer, and communicating the fourth slots with the third slots correspondingly; later filling a metal paste into the third slots and the fourth slots and allowing a level of the metal paste higher than a surface of the fourth dielectric layer; lastly, grinding the metal paste with the level higher than the surface of the fourth dielectric layer to make a surface of the metal paste flush with the surface of the fourth dielectric layer and form a plurality of the; second conductive circuits wherein the respective second conductive circuits are electrically connected with the respective first conductive circuits;
Step S5: covering the fourth dielectric layer with an outer protective layer;
Step S6: forming a plurality of openings on the outer protective layer and at least one of the openings located around the chip area on the second surface of the respective dies so that the respective second conductive circuits are exposed through the respective openings to form a bonding pad in each of the openings; and
Step S7: performing cutting to form a plurality of the FOWLP units each of which includes at least one of the dies.

2. The FOWLP unit as claimed in claim 1, wherein the substrate includes silicon (Si) substrate, glass substrate, and ceramic substrate.

3. The FOWLP unit as claimed in claim 1, wherein the metal paste which forms the first conductive circuits and the second conductive circuits includes silver paste, nano-scale silver paste, copper paste, and nano-scale copper paste.

4. The FOWLP unit as claimed in claim 1, wherein the first surface of the die is disposed on the substrate by a die attach film (DAF).

5. The FOWLP unit as claimed in claim 1, wherein a solder ball is disposed on the opening and electrically connected to the bonding pad in the opening; wherein the FOWLP unit is electrically connected and mounted to a printed circuit board (PCB) by the solder ball.

6. The FOWLP unit as claimed in claim 1, wherein the FOWLP unit further includes at least two of the dies; wherein the step S7 is a step of performing cutting to form a plurality of the FOWLP units each of which includes at least two of the dies.

7. The FOWLP unit as claimed in claim 6, wherein the at least two of the dies are cut from the same wafer or different wafers.
